(19) United States
(12) Patent Application Publication
(10) Pub. No.: US 2009/0059461 A1
(43) Pub. Date: Mar. 5, 2009

(54) ELECTROSTATIC CHUCK

(75) Inventors: Hiroshi Yonekura, Nagano (JP); Tadayoshi Yoshikawa, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/171,458

(22) Filed: Jul. 11, 2008

(30) Foreign Application Priority Data
Aug. 29, 2007 (JP) 2007-222470

(51) Int. Cl. H01L 21/683

(52) U.S. Cl. 361/234

(57) ABSTRACT

An electrostatic chuck of the invention includes a base portion; a heat insulating layer bonded onto the base portion; and a chuck function portion bonded on the heat insulating layer and composed by providing a heater electrode and an electrostatic chuck (ESC) electrode in a ceramic substrate portion. Adhesive layers are respectively provided on the both surface sides of the heat insulating layer. In the case where the base portion and the chuck function portion are bonded together with high adhesion strength, openings are formed in the heat insulating layer and are filled with the adhesive layers.

### CROSS-REFERENCE TO RELATED APPLICATIONS

This application is based on and claims priority of Japanese Patent Application No. 2007-222470 filed on Aug. 29, 2007, the entire contents of which are incorporated herein by reference.

### BACKGROUND OF THE INVENTION

1. Field of the Invention

The present invention relates to an electrostatic chuck, more specifically to an electrostatic chuck with a heater to be employed in various manufacturing apparatuses in order to control a temperature of a wafer during a semiconductor wafer process or the like.

2. Description of the Related Art

Heretofore, a manufacturing apparatus used in a semiconductor wafer process or the like (a plasma chemical vapor deposition (CVD) apparatus, a dry etching apparatus or the like) is provided with an electrostatic chuck onto which a wafer is placed and electrostatically chucked so that a temperature of the wafer can be controlled during various processes. For example, in the dry etching apparatus, so as to prevent the temperature of the wafer from rising over a predetermined level during the plasma processing, a cooling jacket is built in a base plate and the wafer is cooled such that the temperature thereof is uniformly set at a certain temperature.

In recent years, there has been increasing demand for electrostatic chuck in which a heater is built in order to accurately process a wafer at a high temperature, to finely process a wafer with high-temperature etching, or the like. Moreover, in the electrostatic chuck with a heater, a decrease of temperature variation and a finer temperature control in a wafer is required even more than ever.

Japanese Unexamined Patent Application Publication No. Hei 6-326179 discloses a long-life and sophisticated electrostatic chuck with a configuration in which: a chuck function portion is formed by covering an electrode whose both surface sides with insulating dielectric layers; and the chuck function portion and a plate portion are bonded to each other with an adhesive layer made of a fluorine-modified organopolysiloxane composition.

Meanwhile, Japanese Patent Application Publication No. Hei 11-297805 discloses a technique of securing evenness in a wafer-chucking surface and preventing the peeling-off of an adhesive layer in an electrostatic chuck in which a ceramic insulating plate is bonded onto a metal base with the adhesive layer. Specifically, these objects are achieved by employing, as the adhesive layer, a layer containing a butadiene-acrylonitrile copolymer or the like and a hindered phenol antioxidant.

Here, in an electrostatic chuck with a heater, a wafer is heated to be control at a predetermined temperature, and thus such an electrostatic chuck needs to have a still higher temperature rising rate so as to process the wafer efficiently.

However, in an electrostatic chuck with a heater composed by adhering a chuck function portion in which a heater electrode and an ESC electrode are built, on a base portion with an adhesive layer, the adhesive layer is too thin to have sufficiently good heat insulation property. Accordingly, such an electrostatic chuck has a problem that heat generated by the heater electrode is likely to diffuse toward the base portion and, as a result, sufficient temperature rising rate can not be obtained on the upper surface side of the chuck function portion.

### SUMMARY OF THE INVENTION

An object of the present invention is to provide an electrostatic chuck with a heater in which a sufficient temperature rising rate can be obtained and a wafer is processed efficiently.

The present invention relates to an electrostatic chuck, which includes a base portion, a heat insulating layer bonded on the base portion; and a chuck function portion bonded on the heat insulating layer, and composed by providing a heater electrode and an electrostatic chuck (ESC) electrode in a ceramic substrate portion.

According to the present invention, the chuck function portion is provided to be bonded on the base portion via the heat insulating layer (made of silicone rubber or the like). More specifically, adhesive layers are respectively provided on the both surface sides of the heat insulating layer, and the base portion and the chuck function portion are bonded to the heat insulating layer with the adhesive layers, respectively.

The chuck function portion includes the heater electrode and the ESC electrode, and the wafer is heated by the heater electrode and is controlled at a predetermined temperature under a condition where a wafer is chucked onto the chuck function portion.

In the present invention, since the sheet-like heat insulating layer is used, unlike the case where the base portion and the chuck function portion are bonded together only with an adhesive layer, a thickness of the heat insulating layer can be set uniformly and quite thickly. Thus, sufficient heat insulation effect can be obtained in the electric chuck.

Accordingly, heat generated by a heater electrode is prevented from diffusing to the base portion side, and thus the heat is efficiently conducted toward the upper surface of the chuck function portion (toward a wafer). As a result, the temperature rising rate of the electrostatic chuck becomes high, and thus the wafer is efficiently heated and controlled at a predetermined temperature. Accordingly, throughput of the wafer process can be markedly improved than the prior art.

In a preferable mode of the present invention, the heat insulating layer is provided with a plurality of openings, and the openings are filled with the adhesive layers. In general, the heat insulating layer made of silicone rubber or the like is likely to have poor adhesion property to other members. As the countermeasure, the openings are provided in the heat insulating layer, and are filled with the adhesive layers. By this matter, in regions corresponding to the openings, the base portion and the chuck function portion are directly bonded by using the adhesive layers, without the heat insulating layer disposed therebetween.

As a result, the base portion and the chuck function portion are bonded together with sufficient adhesion strength overall in the electrostatic chuck. Moreover, since a thermal conductivity of the adhesive layers can be set equally to a thermal conductivity of the heat insulating layer, a heat insulating effect equivalent to the case that the heat insulating layer having no openings is used can be obtained.

Moreover, in the aforementioned invention, a plurality of notch portions which are eat into inside in a peripheral portion of the heat insulating layer may be formed, and the notch portions may be filled with the adhesive layers. In this case, in a central portion of each of the adhesive layers in the notch portions, a gas hole for emitting a gas to an upper surface side of the chuck function portion may be formed.

When doing this, even when gas holes are formed in a peripheral portion of the electrostatic chuck, the base portion and the chuck function portion in the vicinity of the gas holes are directly bonded to each other with the adhesive layers and thus makes the adhesion strength therebetween higher. Accordingly, a leak of the gas from side portions of the gas holes is prevented.

As described above, in the electrostatic chuck according to the present invention, since heat diffusion toward the base portion is prevented and thus a higher temperature rising rate can be achieved, wafers can be processed efficiently.

### BRIEF DESCRIPTION OF THE DRAWINGS

FIG. 1 is a cross-sectional view of an electrostatic chuck of a related art;

FIG. 2 shows temperature rising characteristics of electrostatic chucks of the related art;

FIG. 3 is a cross-sectional view of an electrostatic chuck of a first embodiment of the present invention;

FIG. 4 shows temperature rising characteristics of the electrostatic chuck shown in FIG. 3;

FIG. 5 is a cross-sectional view of an electrostatic chuck of a second embodiment of the present invention;

FIG. 6 is a plan view showing a state of openings of a heat insulating layer in the electrostatic chuck shown in FIG. 5, the heat insulating layer and adhesive layers in FIG. 5 corresponds to a cross section, taken along the line I-I of FIG. 6, of a structure in which the adhesive layer is formed to the heat insulating layer shown in FIG. 6;

FIGS. 7A and 7B are a plan view and a cross-sectional view showing problems in the case where no notch portion is provided in a peripheral portion of the heat insulating layer, FIG. 7B corresponds to a cross section taken along the line II-II of FIG. 7A;

FIGS. 8A and 8B are a plan view and a cross-sectional view showing a state of the peripheral portion of the electrostatic chuck according to the second embodiment of the present invention, FIG. 8B corresponds to a cross section taken along the line III-III of FIG. 8A.

### DESCRIPTION OF THE PREFERRED EMBODIMENTS

Hereinafter, description will be given of embodiments of the present invention with reference to the attached drawings.

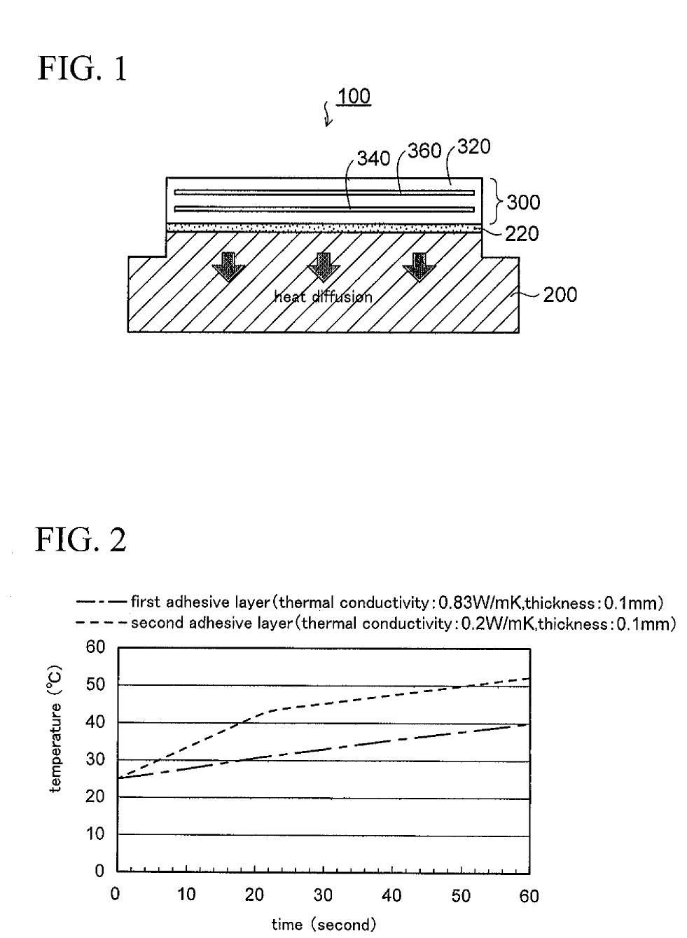

Firstly, a problem in an electrostatic chuck of a related art is explained, before electrostatic chuck according to the embodiment of the present invention is explained. FIG. 1 is a cross-sectional view of the electrostatic chuck of the related art.

As shown in FIG. 1, in the electrostatic chuck 100 of the related art, a chuck function portion 300 is fixed onto an aluminum base portion 200 via an adhesive layer 220. The chuck function portion 300 is composed by building in a heater electrode 340 and an ESC electrode 360 in this order from the bottom in a ceramic substrate 320.

When a wafer is placed on this ceramic substrate 320 and a predetermined voltage is applied to the ESC electrode 360, the wafer is electrostatically chucked onto the ceramic substrate 320. Further, a predetermined voltage is applied to the heater electrode 340, and the heat is generated from the heater electrode 340, thereby the wafer on the ceramic substrate 320 is heated and controlled at a predetermined temperature.

The present inventor examined a temperature rising rate of the electrostatic chuck 100 with the above configuration. As the adhesive layer 220 in FIG. 1, a first adhesive layer made of silicone with a thermal conductivity of 0.83 W/mK and a thickness of 0.1 mm was used. The heater electrode 340 of the electrostatic chuck 100 was disposed to be separated into two, and the heat was generated from the heater electrode 340a by applying voltage of 200 V to each of the two electrodes. Then, a surface temperature of the ceramic substrate 320 was measured with a thermocouple from when the voltage was applied to each heater electrode 340 to after 60 seconds, and the temperature rising rate of the electrostatic chuck 100 was calculated from the measurement result.

According to the measurement result, as shown in FIG. 2 (data shown in a dashed-dotted line), the surface temperature of the ceramic substrate 320 was approximately 24° C. before the voltage was applied to each heater electrode 340, and increased up to 40° C. after 60 seconds from the voltage application. From this measurement result, the temperature rising rate attained with the electrostatic chuck 100 was derived as 0.26° C./sec. This temperature rising rate (0.26° C./sec) indicates that, for example, in the case where a wafer is set at 100° C., it takes a little under 5 minutes after the voltage application. Accordingly, in the electrostatic chuck 100, efficiency of the wafer processing is bad and a sufficient throughput cannot be achieved.

Accordingly, in order to improve the temperature rising rate, the present inventor conducted a similar experiment, as the adhesive layer 220 shown in FIG. 1, by changing the above first adhesive layer to a second adhesive layer (thermal conductivity: 0.2 W/mK, thickness: 0.1 mm) having a thermal conductivity lower than that of the above first adhesive layer.

According to the measurement result, as shown in FIG. 2 (data shown in a dashed line), the surface temperature of the ceramic substrate 320 was approximately 24° C. before the voltage was applied to each heater electrode 340, and became approximately 42° C. after 20 seconds from the voltage application. This shows that the temperature rising rate during the first 20 seconds was significantly improved. However, between from after 20 seconds to 60 seconds, sufficient heat insulation property is not obtained, and the surface temperature increased from 42° C. up to no more than 52° C. From this measurement result, the average temperature rising rate of this electrostatic chuck 100 was derived as 0.47° C./sec, it was obtained only approximately 1.8 times to the case that the first adhesive layer having the high thermal conductivity was used, and a sufficiently high temperature rising rate was not obtained.

As still another conceivable improvement measure, to increase the heat insulation property by thickening the thickness of the adhesive layer 220 is considered. However, since the adhesive layer 220 is formed by coating a liquid adhesive agent and heating the liquid adhesive agent to harden it like rubber, when the thickness is thickened, defects in which the variation of the thickness becomes quite bad or the like are generated. As described above, to form a thick and reliable adhesive layer so as to increase the heat insulation property is difficult.

The above problems can be solved with the electrostatic chucks according to the embodiments of the present invention that will be described below.

### First Embodiment

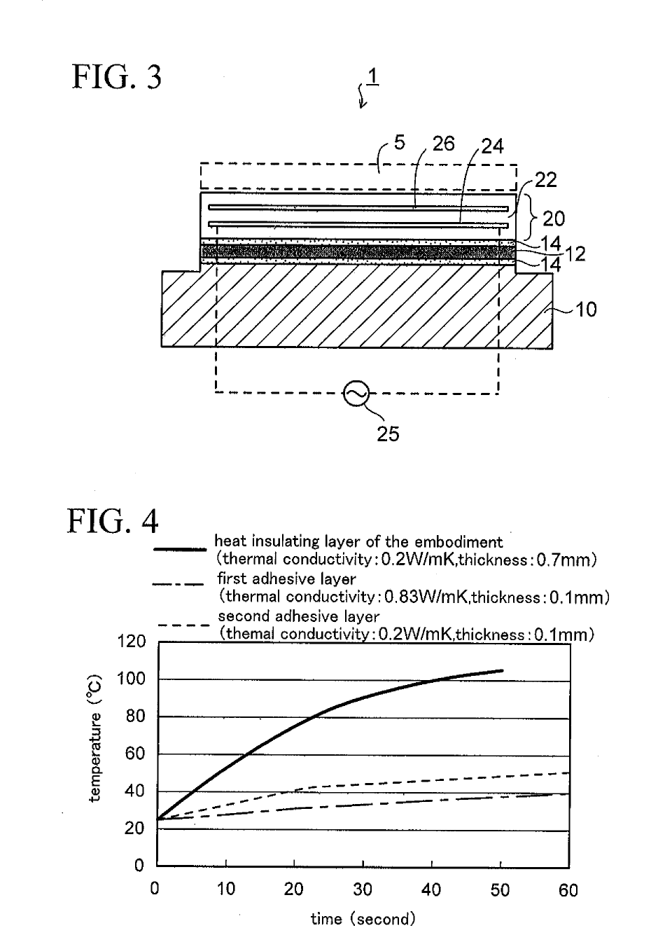

FIG. 3 is a cross-sectional view showing an electrostatic chuck of a first embodiment of the present invention.

As shown in FIG. 3, in the electrostatic chuck 1 of the first embodiment, a chuck function portion 20 is provided on a base portion 10 via a heat insulating layer 12 disposed therebetween. An adhesive layer 14 is formed under the lower surface of the heat insulating layer 12, and the base portion 10 is bonded onto the heat insulating layer 12 with the adhesive layer 14. In addition, another adhesive layer 14 is formed on the upper surface of the heat insulating layer 12, and the chuck function portion 20 is bonded onto the heat insulating layer 12 with the adhesive layer 14.

As described above, the chuck function portion 20 is fixed onto the base portion 10 via the heat insulating layer 12 on the both surface sides of which the adhesive layers 14 is formed.

As a material for the base portion 10, aluminum (or alloys thereof) should preferably be used, but another metal or an insulating material may be used.

The chuck function portion 20 is composed by building in a heater electrode 24 and an ESC electrode 26 in this order from the bottom into a ceramic substrate portion 22. The ceramic substrate portion 22 is formed of alumina (Al₂O₃), silicon carbide (SiC), titanium silicon (TiSi) ceramics, titanium aluminum (TiAl) ceramics or the like.

The ESC electrode 26 may be a unipolar electrode type in which a single electrode is provided in the ceramic substrate portion 22. Otherwise, the ESC electrode 26 may be a bipolar electrode type in which a spiral electrode or a comb-like electrode or the like is used, and positive (+) and negative (−) voltages are respectively applied to a pair of electrodes.

Meanwhile, as the heater electrode 24, a single electrode may be provided in a whole of the ceramic substrate portion 22. Alternatively, the ceramic substrate portion 22 may also be separated into multiple isolated heater zones, and the heater zone made to generate the heat can be selected arbitrarily. For example, by providing the heater electrode 24 in a central portion and a peripheral portion of the ceramic substrate portion 22 in the separated state, the entire ceramic substrate portion 22, only the center portion, or only the peripheral portion can be chosen and can be made to generate heat selectively. Otherwise, in the respective regions that the heat electrode 24 is separated, to control the regions such that the preset temperature is changed in the regions respectively is possible.

The chuck function portion 20 is obtained by sandwiching the heater electrode 24 and the ESC electrode 26 between green sheets for forming the ceramic substrate portion 22, and sintering the stacked body. As a material for the heater electrode 24 and the ESC electrode 26, tungsten paste or the like is used. Then, the chuck function portion 20 is placed on the base portion 10 via the sheet-like heat insulating layer 12 on the both surface sides of which a liquid adhesive agent is coated. Thereafter, the thus-formed stack is thermally-processed so that the adhesive agent is hardened, and consequently the electrostatic chuck 1 of this embodiment is obtained.

When a wafer 5 is placed on the chuck function portion 20 and a predetermined voltage is applied to the ESC electrode 26, the wafer 5 is electrostatically chucked onto the ceramic substrate portion 22 by a force generated between the wafer 5 and the electrostatic chuck 1. Further, a predetermined voltage from an alternating current power source 25 is applied to the heater electrode 24, and the heat is generate from the heater electrode 24, and thus the wafer 5 placed on the ceramic substrate portion 22 is heated and controlled at a predetermined temperature.

One of the characteristics of the electrostatic chuck 1 of this embodiment is that the chuck function portion 20 is disposed on the base portion 10 via the heat insulating layer 12 so that the temperature rising rate of the wafer 5 can be increased, and they are bonded by the adhesive layer 14 each other.

The heat insulating layer 12 is formed of a flexible sheet material (film) made of a material such as silicone rubber, fluorine rubber or urethane rubber. The thermal conductivity of the heat insulating layer 12 is 0.1 W/mK to 0.2 W/mK, and the thickness thereof should preferably be set to 0.5 mm to 1 mm so that the heat insulating layer 12 can provide sufficient heat insulation effect.

Since the heat insulating layer 12 according to this embodiment is formed of a sheet material, the thickness of the heat insulating layer 12 can be set to a uniform and quite large thickness unlike the adhesive layer 220 of the aforementioned related art. Though the thermal conductivity of the heat insulating layer 12 is equal to the thermal conductivity of the adhesive layer 220 of the related art, the thickness of the heat insulating layer 12 can easily be set 5 times to 10 times (or more) as large as that of the adhesive layer 220. Accordingly, the heat insulating layer 12 provides higher heat insulation effect.

In this embodiment, since the heat insulation property of the electrostatic chuck 1 is mostly decided by the characteristics of the heat insulating layer 12, the adhesive layers 14 may be made of any material instead of silicone, irrespective of thermal conductivity.

The present inventor examined a temperature rising rate of the electrostatic chuck 1 of this embodiment. As the heat insulating layer 12, a layer made of silicone rubber with a thermal conductivity of 0.2 W/mK and a thickness of 0.7 mm was used. The heater electrode 24 was disposed to be separated into two, and a voltage of 200 V was applied to each of the two electrodes, and it was made to generate the heat from the heater electrode 24. Then, a surface temperature of the ceramic substrate portion 22 was measured with a thermocouple from when the voltage was applied to each heater electrode 24 to after 50 seconds, and the temperature rising rate of the electrostatic chuck 1 was calculated from the measurement result.

According to the measurement result, as shown in FIG. 4 (data shown in a bold line), the surface temperature of the ceramic substrate portion 22 was approximately 24° C. before the voltage was applied to each heater electrode 24, and became approximately 75° C. after 20 seconds from the voltage application, and the temperature rising rate was markedly improved than the aforementioned related art. Moreover, the surface temperature increased up to approximately 105° C. after 50 seconds from the voltage application.

In FIG. 4, the temperature rising rate characteristics of the aforementioned related art shown in FIG. 2 are shown again as comparative examples. From this measurement result, it turned out that the average temperature rising rate of the electrostatic chuck 1 of this embodiment was derived as 1.66° C./sec, and the rising rate of 3.5 times to 6.4 times in comparison with the electrostatic chucks of the aforementioned related art is obtained.

For example, in the case where the temperature of the wafer is set at 100° C., the temperature reaches to 100° C. with approximately 46 seconds after the voltage application. Thereby the efficiency of the wafer processing is markedly improved than the related art, and a sufficient throughput is achieved.

As has been described, in the electrostatic chuck 1 of this embodiment has a configuration in which the chuck function portion 20 is bonded onto the base portion 10 via the heat insulating layer 12 by using adhesive layers 14. Since the heat insulating layer 12 is formed of a sheet material, the thickness of the heat insulating layer 12 can be easily set thickly unlike the adhesive layer of the related art, and thus the heat insulation effect is markedly improved. Accordingly, since the heat generated by the heater electrode 24 is well-insulated by the heat insulating layer 12, more heat comes to diffuse toward the upper surface of the ceramic substrate portion 22, and thus heat is efficiently conducted to the wafer 5. By this matter, the wafer 5 is quickly heated and controlled at a predetermined temperature, the throughput of wafer processing is markedly improved than the related art.

The electrostatic chuck of this embodiment may preferably be used in a CVD apparatus, a dry etching apparatus or the like, which are used in a semiconductor wafer process and a manufacturing process of an element substrate for a liquid crystal display or the like.

### Second Embodiment

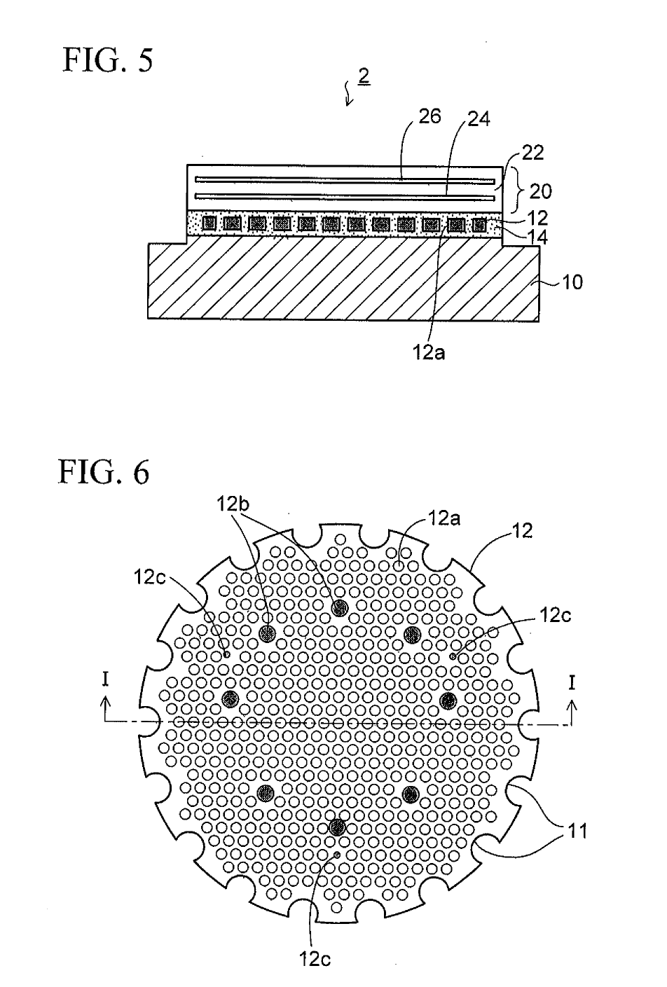

FIG. 5 is a cross-sectional view showing an electrostatic chuck of a second embodiment of the present invention. FIG. 6 is a plan view showing a state of openings in a heat insulating layer of the electrostatic chuck of FIG. 5. In the following description of the second embodiment, the same elements as those of the first embodiment are denoted by the same reference numerals, and description thereof will be omitted.

In the electrostatic chuck 1 (FIG. 3) of the aforementioned first embodiment, the sheet-like heat insulating layer 12 is employed without being processed, and the adhesive layers are formed on the both surface sides of the heat insulating layer 12, and the chuck function portion 20 and the base portion 10 are bonded via the heat insulating layer 12.

The heat insulating layer 12 which is formed of a material such as silicone rubber or fluorine rubber has relatively poor adhesion property to other members. Accordingly in the bonding method of the first embodiment, the case that sufficient adhesion strength between the heat insulating layer 12 and the base portion 10 can not obtained is supposed.

In the electrostatic chuck of the second embodiment, the adhesion strength between the base portion 10 and the chuck function portion 20 can be improved.

As shown in FIG. 5, in the electrostatic chuck 2 of the second embodiment, a plurality of openings 12a are formed in the heat insulating layer 12, and not only the adhesive layers 14 are formed on the upper and lower surfaces of the heat insulating layer 12, but also the adhesive layer 14 is filled in the openings 12a so as to connect the adhesive layers 14 on these surfaces. Then, the base portion 10 is bonded onto the heat insulating layer 12 by the adhesive layers 14 formed on the lower surface and in the openings 12a of the heat insulating layer 12. Also, the chuck function portion 20 is bonded onto the heat insulating layer 12 by the adhesive layers 14 formed on the upper surface and in the openings 12a of the heat insulating layer 12.

As described above, the chuck function portion 20 is bonded onto the base portion 10 via the heat insulating layer 12 with openings 12a, which is sandwiched by the adhesive layers 14.

The electrostatic chuck 2 of the second embodiment has a bonded structure similar to that of the first embodiment (FIG. 3) in a portion where the heat insulating layer 12 exists. However, in the openings 12a of the heat insulating layer 12 of the second embodiment, the base portion 10 and the chuck function portion 20 are directly bonded together by using the adhesive layers 14 without use of the heat insulating layer 12 having poor adhesion property. Here, the adhesive layers 14 have a poor adhesion property to the heat insulating layer 12 (silicone rubber or fluorine rubber), but have good adhesion property to the base portion 10 (aluminum) and the ceramic substrate portion 22 of the chuck function portion 20.

Accordingly, even if the adhesion strength between the heat insulating layer 12 and the base portion 10 as well as between the heat insulating layer 12 and the chuck function portion 20 is low in the portions where the heat insulating layer 12 exists, this adhesion strength is high in the openings 12a of the heat insulating layer 12. As a result, as overall in the electrostatic chuck 2, the base portion 10 and the chuck function portion 20 are bonded together with sufficient adhesion strength.

The total area of the openings 12a should preferably be set to 50% to 90% of the entire area (outer-shape area) of the heat insulating layer 12 so that sufficient adhesion strength can be secured between the base portion 10 and the chuck function portion 20. In other words, the total area of the portions, in contact with the adhesive layers 14, of the heat insulating layer 12 is set to 50% to 10% of the entire area (outer-shape area) of the heat insulating layer 12.

The thermal conductivity (0.2 W/mK) can be equally set between the adhesive layers 14 and the heat insulating layer 12 by using the adhesive layer made of a silicone or the like. Accordingly, even though the total area of the openings 12a of the heat insulating layer 12 is made larger, since the openings 12a are filled with the adhesive layers 14, the heat insulation effect equally to the case that the heat insulating layer 12 having no openings like the first embodiment is used can be obtained. In other words, the electrostatic chuck 2 of the second embodiment has sufficient heat insulation effect, and even when the heat insulating layer 12 is formed of a material having poor adhesion property to other members, the base portion 10 and the chuck function portion 20 are bonded together with sufficient adhesion strength. Moreover, in the plan view of FIG. 6, the heat insulating layer 12 is provided with eight gas holes 12b for supplying an inert gas, such as helium (He), to an interface between the chuck function portion 20 and a wafer, in addition to the openings 12a for improving the adhesion strength. By flowing the inert gas to an interface between the chuck function portion 20 and a wafer, the heat generated from the chuck function portion 20 can be efficiently conducted to the wafer.

Moreover, the heat insulating layer 12 is also provided with three lift-pin holes 12c into which respective lift pins for moving a wafer up and down are inserted. By moving the wafer up and down with the lift pins, the wafer can be automatically convey with a conveyor robot.

In the portions of the chuck function portion 20, the portions corresponding to the gas holes 12b and the lift-pin holes 12c of the heat insulating layer 12, openings (not shown) are respectively formed, and thus supply routes for the inert gas and drive spaces for the lift pins are secured.

In addition to the above openings, the heat insulating layer 12 are also provided with temperature-sensor holes (not shown) into which temperature sensors are respectively to be inserted, and wiring holes (not shown) into which wires to be connected to the ESC electrode 26 and the heater electrode 24 are respectively inserted, or the like.

Moreover, as shown in FIG. 6, a plurality of semicircular notch portions 11 which eat into an inside are also formed along a circumference thereof in the periphery portion of the heat insulating layer 12 of the second embodiment.

A state of the cross-sectional view of the heat insulating layer 12 and the adhesive layers 14 shown in FIG. 5 corresponds to a cross section, taken along the line I-I of FIG. 6, of a structure in which adhesive layers 14 is formed to the heat insulating layer 12 in FIG. 6.

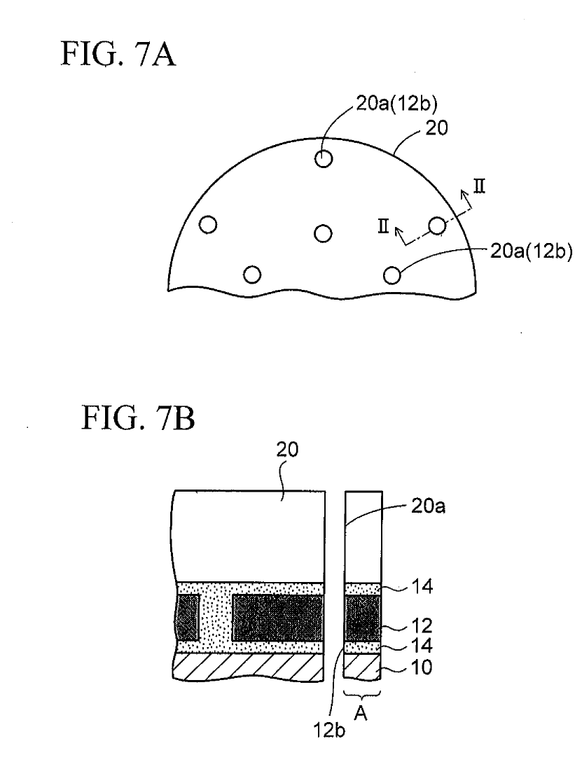

Hereinbelow, a function of the notch portions 11 of the heat insulating layer 12 will be explained. As shown in FIG. 7A, in the chuck function portion 20, gas emitting holes 20a are often provided in a peripheral portion in addition to in a central portion thereof. Accordingly, as shown in FIG. 7B (a partial cross-sectional view taken along the line II-II of FIG. 7A), in the case where the peripheral portion of the heat insulating layer 12 is located in a position corresponding to the gas emitting holes 20a in the peripheral portion of the chuck function portion 20, the openings 12b are provided in the peripheral portion of the heat insulating layer 12.

In this case, since the heat insulating layer 12 exists in an outside of the gas holes 12b, the base portion 10 and the chuck function portion 20 are bonded together via the heat insulating layer 12 by using the adhesive layers 14 on the both surface sides of the heat insulating layer 12 (Part A in FIG. 7B). As mentioned above, since the adhesion strength between the layers is low in the portions where the heat insulating layer 12 exists, the gas may possibly leak from the interface between the heat insulating layer 12 and the adhesive layers 14.

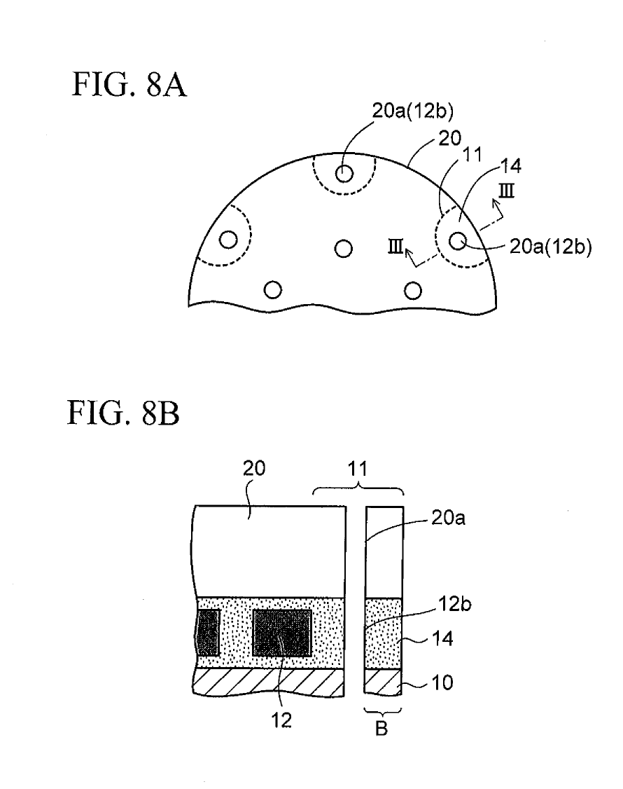

Accordingly, as shown in FIGS. 8A and 8B, in this embodiment, semicircular notch portions 11 each having a larger area than each gas emitting holes 20a are provided in the portion corresponding to the gas emitting holes 20a of the chuck function portion 20, of the heat insulating layer 12.

When the heat insulating layer 12 is sandwiched between the adhesive layers 14, the adhesive layers 14 is also formed in the notch portions 11. Then, after the chuck function portion 20 is disposed on the heat insulating layer 12, the gas holes 12b (shown in FIG. 8B) are respectively formed in the adhesive layers 14 filled in the notch portions 11 of the heat insulating layer 12, through the gas emitting holes 20a of the chuck function portion 20.

As a result, in the peripheral portion (Part B in FIG. 8B) outside from the gas holes 12b in the heat insulating layer 12, the base portion 10 and the chuck function portion 20 are directly bonded to each other by the adhesive layers 14. Accordingly, the adhesion strength between the base portion 10 and the chuck function portion 20 can be set high, and thus, the gas leaking in the peripheral portion of the electrostatic chuck 2 is prevented.

Meanwhile, the lift-pin holes are respectively formed in the adhesive layers 14 filled in lift-pin holes 12c of the heat insulating layer 12, through the lift-pin holes (not shown) provided in the chuck function portion 20. Similarly, the temperature-sensor holes are respectively formed in the adhesive layers 14 filled in the temperature-sensor holes of the heat insulating layer 12, while the wiring holes are respectively formed in the adhesive layers 14 filled in the wiring holes in the heat insulating layer 12, and the temperature sensors and wires to be connected to the heater electrode 24 and the ESC electrode 26 are provided in these holes.

In the electrostatic chuck 2 of the second embodiment, as similar to the first embodiment, the heat insulating layer 12 is provided between the base portion 10 and the chuck function portion 20. This makes it possible to increase the temperature rising rate of the electrostatic chuck 2, and the wafer is efficiently processed.

In addition, the adhesive layers 14 are filled in the openings 12a provided in the heat insulating layer 12. Accordingly, even when the adhesion property between the heat insulating layer 12 and the adhesive layers 14 is bad, a sufficient heat insulation effect can be secured, and the base portion 10 and the chuck function portion 20 are bonded together with sufficient adhesion strength. Thus, the electrostatic chuck 2 can be improved in reliability.

What is claimed is:

1. An electrostatic chuck, comprising:
a base portion;
a heat insulating layer bonded on the base portion; and
a chuck function portion bonded on the heat insulating layer, and composed by providing a heater electrode and an electrostatic chuck (ESC) electrode in a ceramic substrate portion.

2. The electrostatic chuck according to claim 1, wherein
adhesive layers are provided on a both surface sides of the heat insulating layer, and
the base portion and the chuck function portion are bonded to the heat insulating layer by the adhesive layers respectively.

3. The electrostatic chuck according to claim 1, wherein
a plurality of openings are formed in the heat insulating layer,
the openings are filled with the adhesive layers, and
in regions corresponding to the openings of the heat insulating layer, the base portion and the chuck function portion are directly bonded to each other by the adhesive layers in the openings.

4. The electrostatic chuck according to claim 3, wherein the total area of the openings is 50% to 90% to the entire area of the heat insulating layer.

5. The electrostatic chuck according to claim 3, wherein
a plurality of notch portions are formed in a peripheral portion of the heat insulating layer, the notch portions eating into an inside of the heat insulating layer,
the notch portions are filled with the adhesive layers, and
in a central portion of each of the adhesive layers in the notch portions, a gas hole for emitting a gas toward the upper surface of the chuck function portion is formed.

6. The electrostatic chuck according to claim 2, wherein
the heat insulating layer is formed of a sheet material, and
the adhesive layer is formed by hardening a liquid adhesive agent.

7. The electrostatic chuck according to claim 3, wherein a thermal conductivity of the heat insulating layer is equal to a thermal conductivity of the adhesive layers.

8. The electrostatic chuck according to claim 1, wherein
a thermal conductivity of the heat insulating layer is 0.1 W/mK to 0.2 W/mK, and
a thickness of the heat insulating layer is 0.5 mm to 1 mm.

9. The electrostatic chuck according to claim 1, wherein the heat insulating layer is made of silicone rubber, fluorine rubber or urethane rubber.
